(19) United States
(12) Patent Application Publication
(10) Pub. No.: US 2026/0013280 A1
(43) Pub. Date: Jan. 8, 2026

(54) DOUBLE-SIDED DISPLAY PIXEL PACKAGE STRUCTURE AND METHOD FOR FABRICATING THE SAME

(71) Applicant: INGENTEC CORPORATION, Zhunan Township (TW)

(72) Inventors: Hsiao-Lu CHEN, Zhunan Township (TW); Chia-Pin WANG, Zhunan Township (TW); Ai-Sen LIU, Zhunan Township (TW)

(73) Assignee: INGENTEC CORPORATION, Zhunan Township (TW)

(21) Appl. No.: 18/887,987

(22) Filed: Sep. 17, 2024

(30) Foreign Application Priority Data
Jul. 4, 2024 (TW) 113125171

(51) Int. Cl. H01L 33/54; H01L 25/075; H01L 33/00; H01L 33/56; H01L 33/62

(52) U.S. Cl. CPC H10H 20/853; H01L 25/0753; H10H 20/01; H10H 20/854; H10H 20/857; H10H 20/032; H10H 20/0362

(57) ABSTRACT

The disclosure describes a double-sided display pixel package structure and a method for fabricating the same. The double-sided display pixel package structure includes a transparent substrate, conduction bumps, a dummy diode structure, light-emitting diode (LED) structures, a first protection layer, a conduction layer, a second protection layer, and a half mirror film. The transparent substrate is penetrated with conduction vias. The conduction bumps are respectively formed on the conduction vias. The dummy diode structure and the LED structures are respectively formed on the conduction bumps. The first protection layer, formed on the transparent substrate, surrounds the conduction bumps, the dummy diode structure, and the LED structures. The conduction layer and the second protection layer are sequentially formed on the first protection layer, the dummy diode structure, and the LED structures. The half mirror film is formed on the substrate, the protection layers, and the conduction layer.

### BACKGROUND OF THE INVENTION

This application claims priority for the TW application No. 11/312,5171 filed on 4 Jul. 2024, the content of which is incorporated by reference in its entirely.

### FIELD OF THE INVENTION

The present invention relates to package technology, particularly to a double-sided display pixel package structure and a method for fabricating the same.

### DESCRIPTION OF THE RELATED ART

Light-emitting diodes (LEDs), made of semiconductor materials, emit light with various colors, such as red right, green light, yellow light, and blue right. When a forward voltage is applied to the P-N junction of the semiconductor material, the light-emitting diode emits light. LEDs have advantages of low power consumption, high brightness, low voltage, easy matching with integrated circuits, easy driving, and long service life. Therefore, they have been widely used in lighting devices and various industries.

In the method of packaging a LED, the electrodes of the LED are connected to a package substrate by wire bonding. The top electrode of the LED is electrically connected to a package substrate through soldering wires. Since multiple light-emitting diodes need to be wire-bonded one by one, the production speed and yield cannot be satisfied in the application of multiple chips. Due to wire bonding, the structure for packaging LEDs is difficultly reduced in volume and impedance. It is difficult for the structure to meet the needs of light, thin, small and high-brightness applications. In addition, the forms of electronic products are becoming increasingly diversified. The double-sided display function has become the main feature of the new generation of electronic products. However, when assembling a double-sided display device, two independent single-sided display devices are first packaged and then the two single-sided display devices are assembled back-to-back. The overall thickness of this double-sided display device is thicker and its weight and cost will also increase accordingly.

To overcome the abovementioned problems, the present invention provides a double-sided display pixel package structure and a method for fabricating the same, so as to solve the afore-mentioned problems of the prior art.

### SUMMARY OF THE INVENTION

The present invention provides a double-sided display pixel package structure and a method for fabricating the same, which simplify a structure and reduce a thickness, a weight, and a cost.

In an embodiment of the present invention, a double-sided display pixel package structure includes a transparent substrate, conduction bumps, a dummy diode structure, light-emitting diode structures, a first protection layer, a conduction layer, a second protection layer, and a half mirror film. The transparent substrate is penetrated with conduction vias. The conduction bumps are respectively formed on the conduction vias. The dummy diode structure and the light-emitting diode structures are respectively formed on the conduction bumps. The first protection layer, formed on the transparent substrate, surrounds the conduction bumps, the dummy diode structure, and the light-emitting diode structures. The conduction layer is formed on the first protection layer, the dummy diode structure, and the light-emitting diode structures. The second protection layer is formed on the conduction layer. The half mirror film, formed on sidewalls of the transparent substrate, the first protection layer, the conduction layer, and the second protection layer and the partial top of the second protection layer, exposes the second protection layer which is directly formed over the light-emitting diode structures.

In an embodiment of the present invention, each of the light-emitting diode structures includes a metal combined substrate, a first epitaxial layer, a second epitaxial layer, and an electrode layer. The metal combined substrate includes a first Invar layer, a first copper layer, and a second copper layer. The first copper layer and the second copper layer are respectively formed on the top surface and the bottom surface of the first Invar layer. The second copper layer is formed between the first Invar layer and the conduction bump. The thickness ratio of the first copper layer to the first Invar layer to the second copper layer is 1:2.5˜3.5:1. The first epitaxial layer, having a first conductivity type, is formed on the first copper layer. The second epitaxial layer, having a second conductivity type opposite to the first conductivity type, is formed on the first epitaxial layer. The electrode layer is formed on the second epitaxial layer. The first protection layer surrounds the metal combined substrate, the first epitaxial layer, the second epitaxial layer, and the electrode layer. The conduction layer is formed on the electrode layer.

In an embodiment of the present invention, the dummy diode structure includes a second Invar layer, a first gold layer, and a second gold layer. The first gold layer and the second gold layer are respectively formed on the top surface and the bottom surface of the second Invar layer. The second gold layer is formed between the second Invar layer and the conduction bump. The thickness ratio of the first gold layer to the second Invar layer to the second gold layer is 1.1:2.5˜3.5:1.1.

In an embodiment of the present invention, the height of each of the light-emitting diode structures is equal to the height of the dummy diode structure.

In an embodiment of the present invention, the first conductivity type is a P type and the second conductivity type is an N type.

In an embodiment of the present invention, the first conductivity type is an N type and the second conductivity type is a P type.

In an embodiment of the present invention, the light-emitting diode structures include green light-emitting diode structures, blue light-emitting diode structures, and red light-emitting diode structures.

In an embodiment of the present invention, the transparent substrate is a glass substrate.

In an embodiment of the present invention, the conduction vias include copper and the conduction bumps include solder.

In an embodiment of the present invention, the first protection layer and the second protection layer insulating transparent glues.

In an embodiment of the present invention, the half mirror film has a thickness of 20˜70 nm.

In an embodiment of the present invention, a method for fabricating a double-sided display pixel package structure includes: providing a transparent substrate penetrated with conduction via sets, wherein each of the conduction via sets includes conduction vias; respectively forming conduction bumps on the conduction vias of each of the conduction via sets; respectively forming a dummy diode structure and light-emitting diode structures on the conduction bumps; forming a first protection layer on the transparent substrate to surround and cover the conduction bumps, the dummy diode structure, and the light-emitting diode structures; removing the first protection layer on the tops of the dummy diode structure and the light-emitting diode structures; forming a conduction layer on the first protection layer, the dummy diode structure, and the light-emitting diode structures to electrically connect to the dummy diode structure and the light-emitting diode structures; forming a second protection layer on the conduction layer; dividing the transparent substrate, the first protection layer, the conduction layer, and the second protection layer to form diode package structures, wherein each of the diode package structures includes the conduction via set and the transparent substrate, the conduction bumps, the dummy diode structure, the light-emitting diode structures, the first protection layer, the conduction layer, and the second protection layer corresponding thereto; arranging the diode package structures on a transient substrate through a removable double-sided adhesive layer; forming a half mirror film on the sidewalls of the transparent substrate, the first protection layer, the conduction layer, and the second protection layer and the partial top of the second protection layer of each of the diode package structures, so as to expose the second protection layer which is directly formed over the light-emitting diode structures; and removing the removable double-sided adhesive layer and the transient substrate from the diode package structures and the half mirror film to obtain double-sided display pixel package structures.

The step of forming the half mirror film on the sidewalls of the transparent substrate, the first protection layer, the conduction layer, and the second protection layer and the partial top of the second protection layer of each of the diode package structures, so as to expose the second protection layer which is directly formed over the light-emitting diode structures includes: respectively arranging blocking blocks on the second protection layer which is directly formed over the light-emitting diode structures; forming the half mirror film on the blocking blocks and the sidewalls of the transparent substrate, the first protection layer, the conduction layer, and the second protection layer and the partial top of the second protection layer of each of the diode package structures; removing blocking blocks and the half mirror film thereon.

In an embodiment of the present invention, the transparent substrate of each of the diode package structures has a shape of a square. The diode package structures on the transient substrate are uniformly spaced. A distance between adjacent two of the diode package structures is 1.2 times a width of the square.

In an embodiment of the present invention, the removable double-sided adhesive layer is an ultraviolet rays (UV) release adhesive layer.

In an embodiment of the present invention, in the step of forming the first protection layer to cover the light-emitting diode structures, the height of the first protection layer minus the height of each of the light-emitting diode structures is equal to 4˜8 μm.

In an embodiment of the present invention, in the step of respectively forming the dummy diode structure and the light-emitting diode structures on the conduction bumps, a laser with a power of 1˜5 watts is applied to the conduction bumps for 15˜60 ms to form the dummy diode structure and the light-emitting diode structures on the conduction bumps respectively.

To sum up, the double-sided display pixel package structure and the method for fabricating the same electrically connect the conduction layer to the dummy diode structure and all the light-emitting diode structures of the same diode package structure and form the half mirror film on the sidewalls of the transparent substrate, the first protection layer, the conduction layer, and the second protection layer and the partial top of the second protection layer of each diode package structure, thereby simplifying a structure and reducing a thickness, a weight, and a cost.

Below, the embodiments are described in detail in cooperation with the drawings to make easily understood the technical contents, characteristics and accomplishments of the present invention.

### BRIEF DESCRIPTION OF THE DRAWINGS

FIG. 1 is a cross-sectional view of a double-sided display pixel package structure according to an embodiment of the present invention;

FIG. 2 is a cross-sectional view of a double-sided display pixel package structure according to another embodiment of the present invention;

FIGS. 3a-3m are top views for the steps of fabricating a double-sided display pixel package structure according to an embodiment of the present invention; and

FIGS. 4a-4m are cross-sectional views for the steps of fabricating a double-sided display pixel package structure according to an embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

When an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

Furthermore, it can be understood that the terms “comprising,” “including,” “having,” “containing,” and “involving” are open-ended terms, which refer to “may include but is not limited to so.” In addition, each of the embodiments or claims of the present invention is not necessary to achieve all the effects and advantages possibly to be generated, and the abstract and title of the present invention is used to assist for patent search and is not used to further limit the claimed scope of the present invention.

Further, in the present specification and claims, the term “comprising” is open type and should not be viewed as the term “consisted of.” In addition, the term “electrically coupled” can be referring to either directly connecting or indirectly connecting between elements. Thus, if it is described in the below contents of the present invention that a first device is electrically coupled to a second device, the first device can be directly connected to the second device, or indirectly connected to the second device through other devices or means. Moreover, when the transmissions or generations of electrical signals are mentioned, one skilled in the art should understand some degradations or undesirable transformations could be generated during the operations. If it is not specified in the specification, an electrical signal at the transmitting end should be viewed as substantially the same signal as that at the receiving end. For example, when the end A of an electrical circuit provides an electrical signal S to the end B of the electrical circuit, the voltage of the electrical signal S may drop due to passing through the source and drain of a transistor or due to some parasitic capacitance. However, the transistor is not deliberately used to generate the effect of degrading the signal to achieve some result, that is, the signal S at the end A should be viewed as substantially the same as that at the end B.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

In the following description, a double-sided display pixel package structure and a method for fabricating the same will be provided, which electrically connect a conduction layer to the dummy diode structure and all the light-emitting diode structures of the same diode package structure and form a half mirror film on the sidewalls of a transparent substrate, a first protection layer, the conduction layer, and a second protection layer and the partial top of the second protection layer of each diode package structure, thereby simplifying a structure and reducing a thickness, a weight, and a cost.

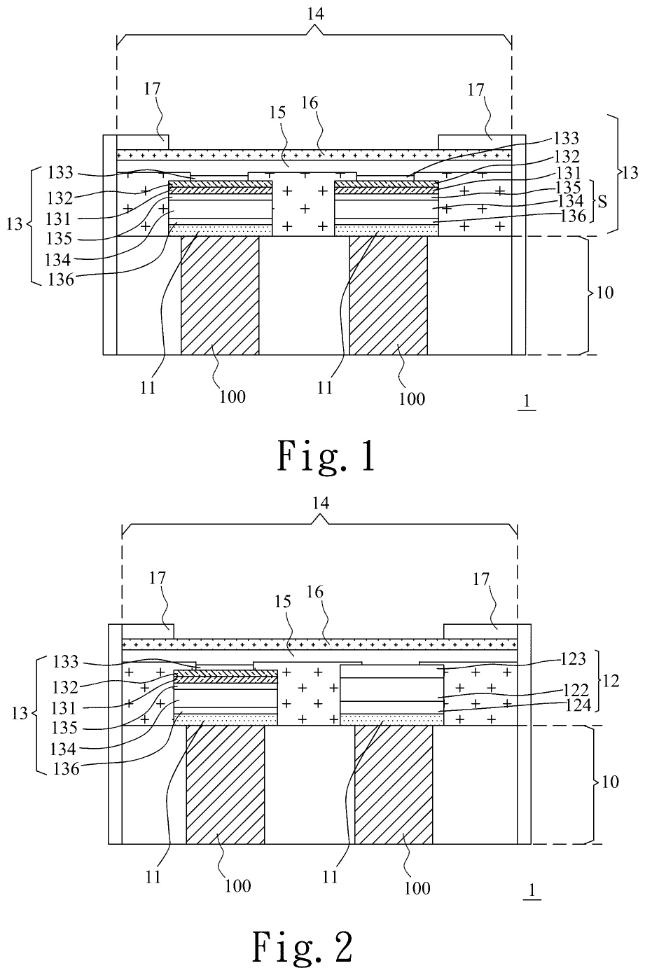

FIG. 1 is a cross-sectional view of a double-sided display pixel package structure according to an embodiment of the present invention. FIG. 2 is a cross-sectional view of a double-sided display pixel package structure according to another embodiment of the present invention. Referring to FIG. 1 and FIG. 2, a double-sided display pixel package structure 1 will be introduced as follows. The double-sided display pixel package structure 1 includes a transparent substrate 10, conduction bumps 11, a dummy diode structure 12, light-emitting diode structures 13, a first protection layer 14, a conduction layer 15, a second protection layer 16, and a half mirror film 17. The first protection layer 14, the conduction layer 15, and the second protection layer 16 can allow light to penetrate. For example, the transparent substrate 10 may be, but not limited to, a glass substrate. The transparent substrate 10 is penetrated with conduction vias 100. The conduction vias 100 may include copper. The conduction bumps 11 may include solder. The light-emitting diode structures 13 include green light-emitting diode structures, blue light-emitting diode structures, and red light-emitting diode structures. The conduction layer 15 may be, but not limited to, an Indium tin oxide (ITO) layer. The first protection layer 14 and the second protection layer 16 may be insulating transparent glues. The thickness of the half mirror film can be 20 to 70 nm. The dummy diode structure 12 and the light-emitting diode structures 13 are respectively formed on the conduction vias 100. The first protection layer 14, formed on the transparent substrate 10, surrounds the conduction bumps 11, the dummy diode structure 12, and the light-emitting diode structures 13. The conduction layer 15 is formed on the first protection layer 14, the dummy diode structure 12, and the light-emitting diode structures 13 and electrically connected to the dummy diode structure 12 and the light-emitting diode structures 13. The second protection layer 16, formed on the sidewalls of the transparent substrate 10, the first protection layer 14, the conduction layer 15, and the second protection layer 16 and the partial top of the second protection layer 16, exposes the second protection layer 16 which is directly formed over the light-emitting diode structures 13. The half mirror film 17 can reflect the light emitted upward by the light-emitting diode structures 13, so that the light can be emitted to locations below the light-emitting diode structures 13. The half mirror film 17 can also allow the light to penetrate.

In some embodiments of the present invention, each of the light-emitting diode structures 13 includes a metal combined substrate S, a first epitaxial layer 131, a second epitaxial layer 132, and an electrode layer 133. The metal combined substrate S includes a first Invar layer 134, a first copper layer 135, and a second copper layer 136. The first Invar layer 134 is a nickel-iron alloy layer. The first copper layer 135 and the second copper layer 136 are respectively formed on the top surface and the bottom surface of the first Invar layer 134. The second copper layer 136 is formed between the first Invar layer 134 and the conduction bump 11. The thickness ratio of the first copper layer 135 to the first Invar layer 134 to the second copper layer 136 is 1:2.5˜3.5:1. The first epitaxial layer 131, having a first conductivity type, is formed on the first copper layer 135. The second epitaxial layer 132 has a second conductivity type opposite to the first conductivity type. The second epitaxial layer 132 is formed on the first epitaxial layer 131. When the first conductivity type is a P type, the second conductivity type is an N type. When the first conductivity type is an N type, the second conductivity type is a P type. The electrode layer 133 is formed on the second epitaxial layer 132. The first protection layer 14 surrounds the metal combined substrate S, the first epitaxial layer 131, the second epitaxial layer 132, and the electrode layer 133. The conduction layer 15 is formed on the electrode layer 133.

In some embodiments of the present invention, the dummy diode structure 12 includes a second Invar layer 122, a first gold layer 123, and a second gold layer 124. The second Invar layer 122 is a nickel-iron alloy layer. The first gold layer 123 and the second gold layer 124 are respectively formed on the top surface and the bottom surface of the second

Invar layer 122. The second gold layer 124 is formed between the second Invar layer 122 and the conduction bump 11. The thickness ratio of the first gold layer 123 to the second Invar layer 122 to the second gold layer 124 is 1.1:2.5˜3.5:1.1. The first protection layer 14 surrounds the second Invar layer 122, the first gold layer 123, and the second gold layer 124. The conduction layer 15 is formed on the first gold layer 123. In a preferred embodiment, the heights of each light-emitting diode structure 13 and the dummy diode structure 12 are equal, so that the top surface of the conduction layer 15 is flat. Each light-emitting diode structure 13 can be coupled to external voltage through the conduction via 100 thereunder, electrically connected to the dummy diode structure 12 through the electrode layer 133 and the conduction layer 15, and then coupled to external voltage through the conduction via 100 under the dummy diode structure 12.

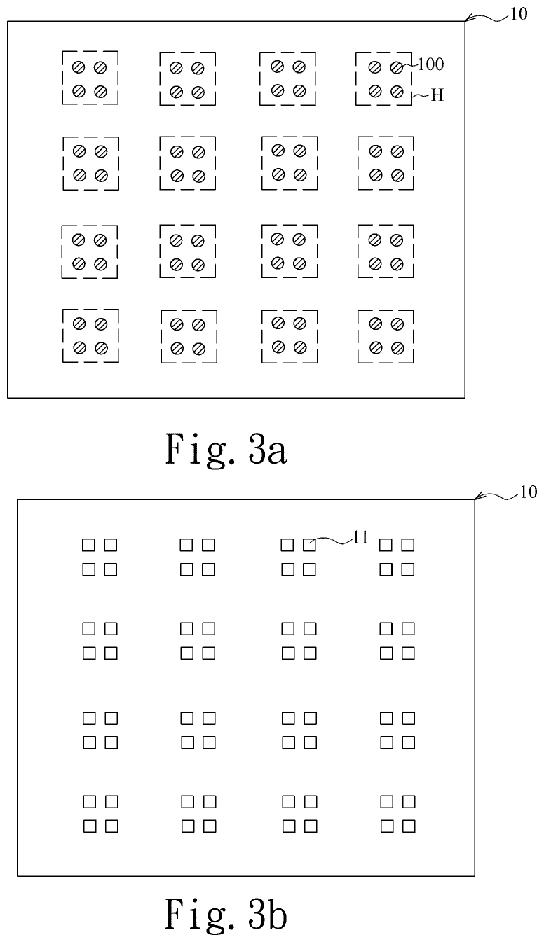

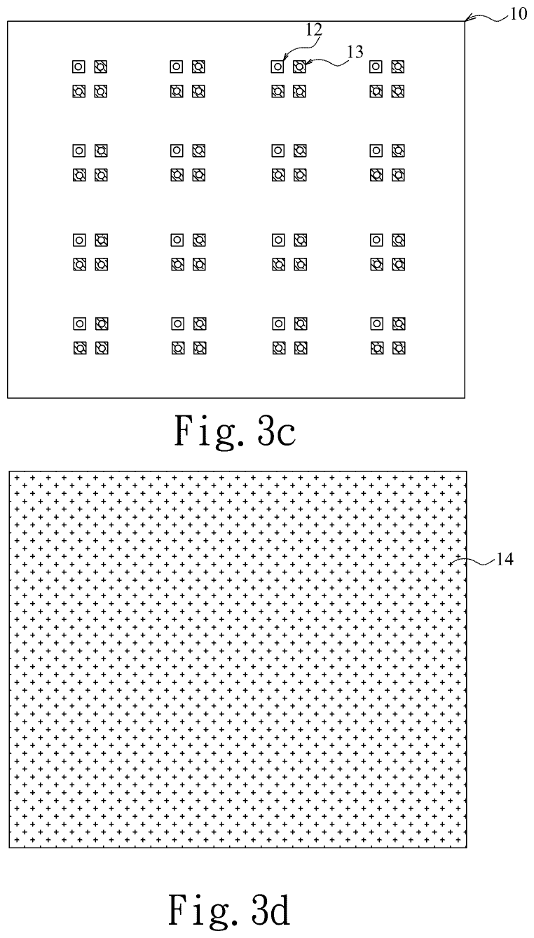

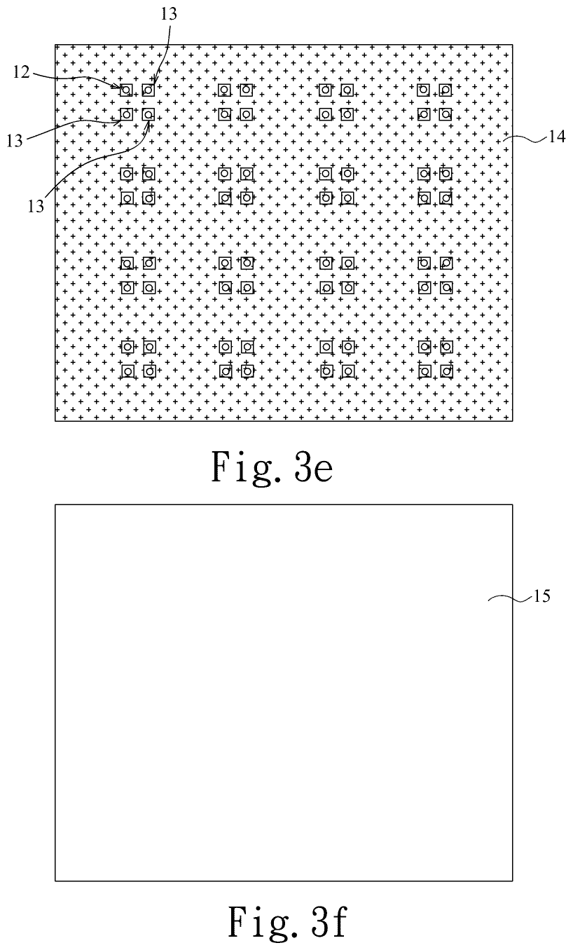

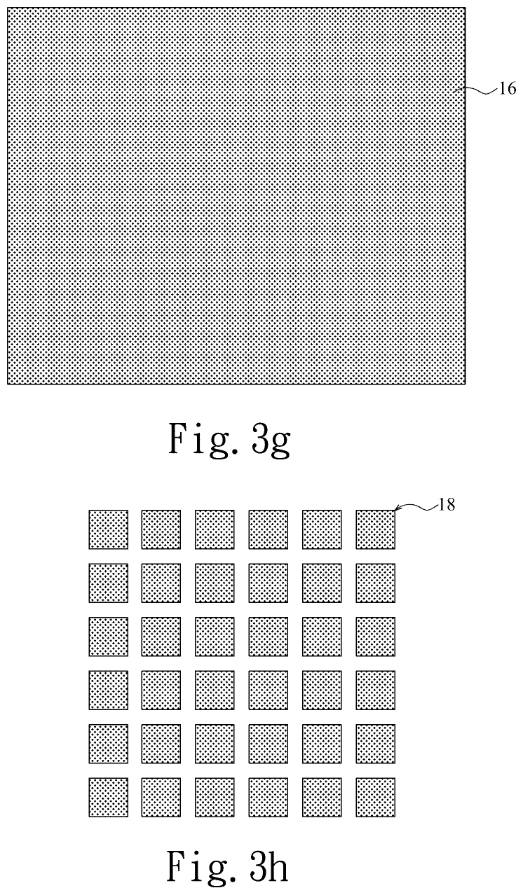

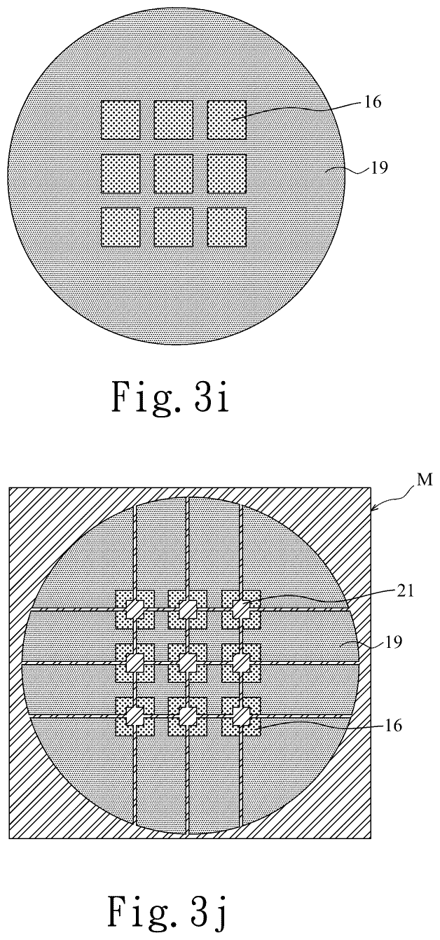

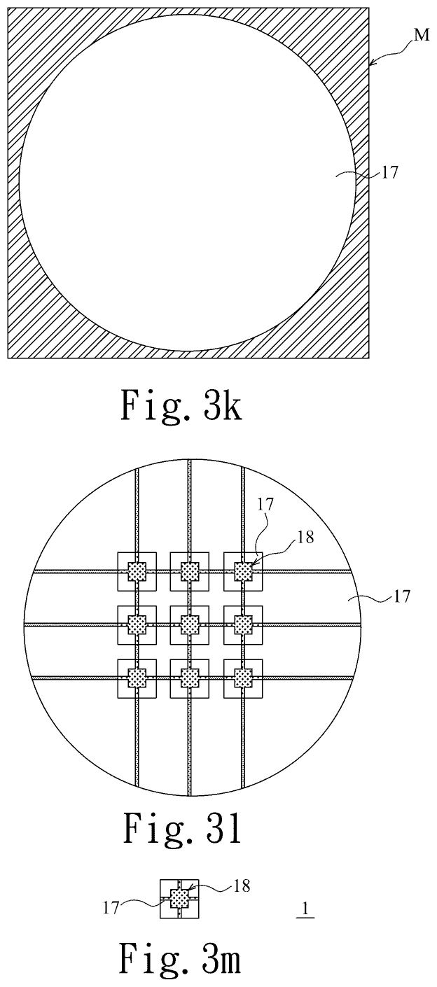

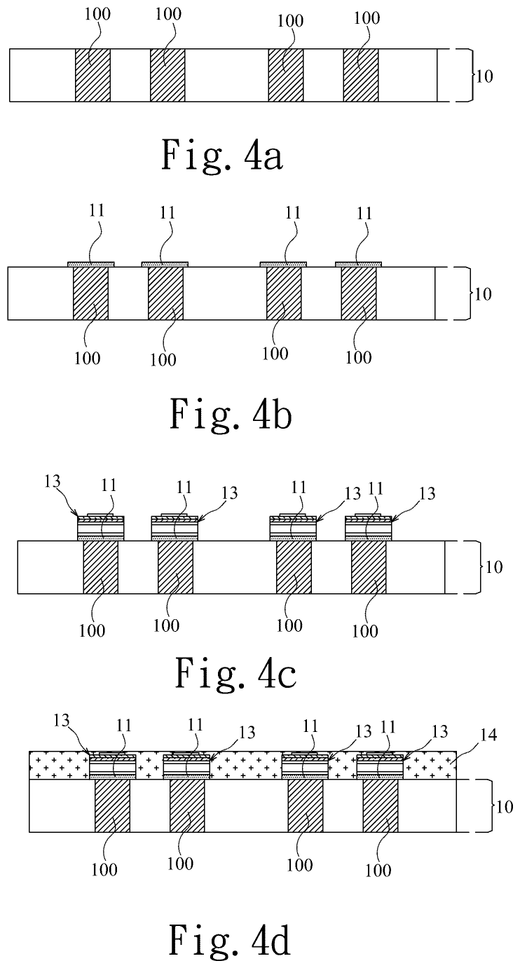

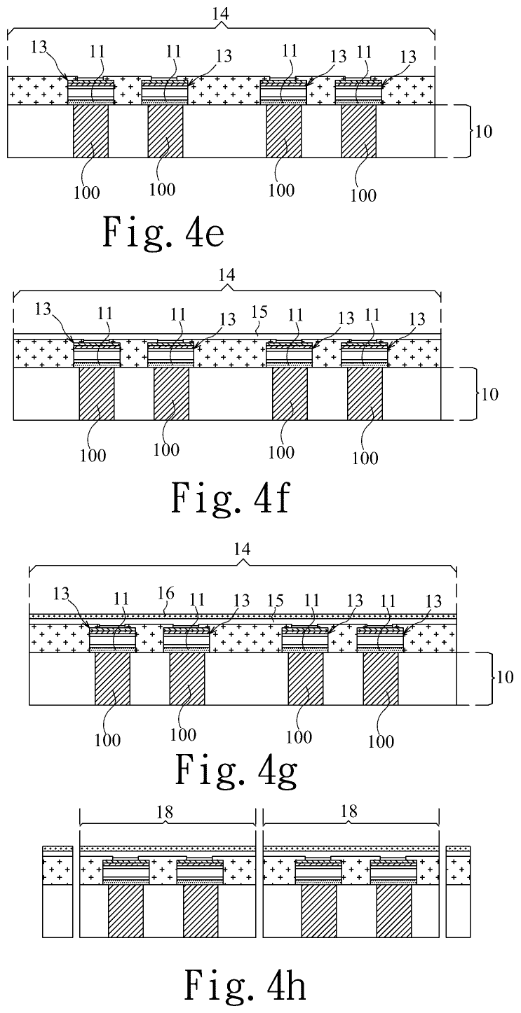

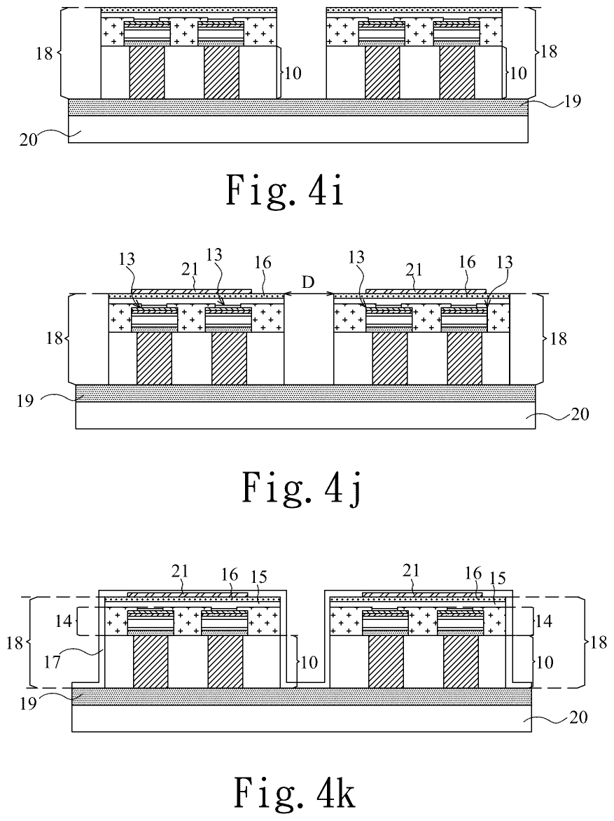

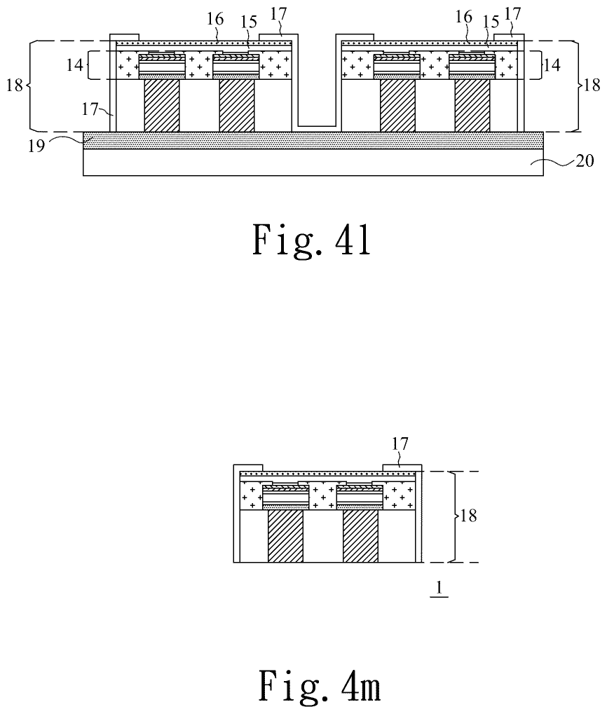

FIGS. 3a-3m are top views for the steps of fabricating a double-sided display pixel package structure according to an embodiment of the present invention. FIGS. 4a-4m are cross-sectional views for the steps of fabricating a double-sided display pixel package structure according to an embodiment of the present invention. FIGS. 3a-3m respectively correspond to FIGS. 4a-4m. Referring to FIGS. 3a-3m and FIGS. 4a-4m, a method for fabricating a double-sided display pixel package structure is introduced as follows. As illustrated in FIG. 3a and FIG. 4a, a transparent substrate 10 penetrated with conduction via sets H is provided, wherein each of the conduction via sets H includes conduction vias 100. As illustrated in FIG. 3b and FIG. 4b, conduction bumps 11 are respectively formed on the conduction vias 100 of each of the conduction via sets H. The conduction bumps 11 can be formed by a printing manner. As illustrated in FIG. 3c and FIG. 4c, a dummy diode structure 12 and light-emitting diode structures 13 are respectively formed on the conduction bumps 11. For example, a laser with a power of 1˜5 watts is applied to the conduction bumps 11 for 15˜60 ms to form the dummy diode structure 12 and the light-emitting diode structures 13 on the conduction bumps 11 respectively. As illustrated in FIG. 3d and FIG. 4d, a first protection layer 14 is formed on the transparent substrate 10 to surround and cover the conduction bumps 11, the dummy diode structure 12, and the light-emitting diode structures 13 using a glue dispensing manner or a spin coating manner. For example, the height of the first protection layer 14 minus the height of each of the light-emitting diode structures 13 is equal to 4˜8 μm. As illustrated in FIG. 3e and FIG. 4e, the first protection layer 14 is removed on the tops of the dummy diode structure 12 and the light-emitting diode structures 13 using a laser or a photolithography process. As illustrated in Fig. 3f and Fig. 4f, a conduction layer 15 is formed on the first protection layer 14, the dummy diode structure 12, and the light-emitting diode structures 13 to electrically connect to the dummy diode structure 12 and the light-emitting diode structures 13. The conduction layer 15 may be formed using a sputtering manner. As illustrated in FIG. 3g and FIG. 4g, a second protection layer 16 is formed on the conduction layer 15 using a glue dispensing manner or a spin coating manner. As illustrated in FIG. 4g, FIG. 3h, and FIG. 4h, the transparent substrate 10, the first protection layer 14, the conduction layer 15, and the second protection layer 16 are divided with a cut wheel to form diode package structures 18. As illustrated in FIG. 3a, FIG. 3c, FIG. 4g, and FIG. 4h, each of the diode package structures 18 includes the conduction via set H and the transparent substrate 10, the conduction bumps 11, the dummy diode structure 12, the light-emitting diode structures 13, the first protection layer 14, the conduction layer 15, and the second protection layer 16 corresponding thereto. As illustrated in FIG. 3i and FIG. 4i, the diode package structures 18 are arranged on a transient substrate 20 through a removable double-sided adhesive layer 19. The removable double-sided adhesive layer 19 may be, but not limited to, an ultraviolet rays (UV) release adhesive layer. In order to form a half mirror film on the sidewalls of the diode package structures 18, the transparent substrate 10 of each of the diode package structures 18 has a shape of a square, the diode package structures 18 on the transient substrate 20 are uniformly spaced, and a distance D between adjacent two of the diode package structures 18 is 1.2 times the width of the square. As illustrated in FIG. 3j and FIG. 4j, an openwork mask M having blocking blocks 21 is arranged on the second protection layer 16 to respectively arrange the blocking blocks 21 on the second protection layer 16 which is directly formed over the light-emitting diode structures 13, thereby exposing the transparent substrate 10, the first protection layer 14, the conduction layer 15, and the second protection layer 16 of each of the diode package structures 18. Referring to FIG. 3k and FIG. 4k and using an evaporation manner, a half mirror film 17 is formed on the sidewalls of the transparent substrate 10, the first protection layer 14, the conduction layer 15, and the second protection layer 16 and the partial top of the second protection layer 16 of each of the diode package structures 18 to simplify a structure and reduce a weight, a thickness, and a cost. As illustrated in FIG. 4k, FIG. 3l, and FIG. 4l, the blocking blocks 21 and the half mirror film 17 thereon are removed. As illustrated in FIG. 4l, FIG. 3m, and FIG. 4m, UV light is irradiated to the removable double-sided adhesive layer 19 to remove the removable double-sided adhesive layer 19 and the transient substrate 20 from the diode package structures 18 and the half mirror film 17 to obtain double-sided display pixel package structures 1. For convenience and clarity, FIG. 3m and FIG. 4m illustrate one double-sided display pixel package structure 1 as an example. The steps of FIG. 4j, FIG. 4k, and FIG. 4l can be replaced by one step. After the step of FIG. 4i, the step of FIG. 4l is directly performed for forming a half mirror film 17 on the sidewalls of the transparent substrate 10, the first protection layer 14, the conduction layer 15, and the second protection layer 16 and the partial top of the second protection layer 16 of each of the diode package structures 18, so as to expose the second protection layer 16 which is directly formed over the light-emitting diode structures 13. Provided that substantially the same result is achieved, the steps of the flowchart shown in FIGS. 4a-4m need not be in the exact order shown and need not be contiguous, that is, other steps can be intermediate.

According to the embodiments provided above, the double-sided display pixel package structure and the method for fabricating the same electrically connect the conduction layer to the dummy diode structure and all the light-emitting diode structures of the same diode package structure and form the half mirror film on the sidewalls of the transparent substrate, the first protection layer, the conduction layer, and the second protection layer and the partial top of the second protection layer of each diode package structure, thereby simplifying a structure and reducing a thickness, a weight, and a cost.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A double-sided display pixel package structure comprising:
a transparent substrate penetrated with conduction vias;
conduction bumps respectively formed on the conduction vias;
a dummy diode structure and light-emitting diode structures respectively formed on the conduction bumps;
a first protection layer, formed on the transparent substrate, surrounding the conduction bumps, the dummy diode structure, and the light-emitting diode structures;
a conduction layer formed on the first protection layer, the dummy diode structure, and the light-emitting diode structures;
a second protection layer formed on the conduction layer; and
a half mirror film formed on sidewalls of the transparent substrate, the first protection layer, the conduction layer, and the second protection layer and a partial top of the second protection layer, exposing the second protection layer which is directly formed over the light-emitting diode structures.

2. The double-sided display pixel package structure according to claim 1, wherein each of the light-emitting diode structures includes:
a metal combined substrate including a first Invar layer, a first copper layer, and a second copper layer, the first copper layer and the second copper layer are respectively formed on a top surface and a bottom surface of the first Invar layer, the second copper layer is formed between the first Invar layer and the conduction bump, and a thickness ratio of the first copper layer to the first Invar layer to the second copper layer is 1:2.5˜3.5:1;
a first epitaxial layer, having a first conductivity type, formed on the first copper layer;
a second epitaxial layer, having a second conductivity type opposite to the first conductivity type, formed on the first epitaxial layer; and
an electrode layer formed on the second epitaxial layer, the first protection layer surrounds the metal combined substrate, the first epitaxial layer, the second epitaxial layer, and the electrode layer, and the conduction layer is formed on the electrode layer.

3. The double-sided display pixel package structure according to claim 2, wherein the dummy diode structure includes a second Invar layer, a first gold layer, and a second gold layer, the first gold layer and the second gold layer are respectively formed on a top surface and a bottom surface of the second Invar layer, the second gold layer is formed between the second Invar layer and the conduction bump, and a thickness ratio of the first gold layer to the second Invar layer to the second gold layer is 1.1:2.5˜3.5:1.1.

4. The double-sided display pixel package structure according to claim 3, wherein a height of each of the light-emitting diode structures is equal to a height of the dummy diode structure.

5. The double-sided display pixel package structure according to claim 2, wherein the first conductivity type is a P type and the second conductivity type is an N type.

6. The double-sided display pixel package structure according to claim 2, wherein the first conductivity type is an N type and the second conductivity type is a P type.

7. The double-sided display pixel package structure according to claim 1, wherein the light-emitting diode structures include green light-emitting diode structures, blue light-emitting diode structures, and red light-emitting diode structures.

8. The double-sided display pixel package structure according to claim 1, wherein the transparent substrate is a glass substrate.

9. The double-sided display pixel package structure according to claim 1, wherein the conduction vias include copper and the conduction bumps include solder.

10. The double-sided display pixel package structure according to claim 1, wherein the first protection layer and the second protection layer insulating transparent glues.

11. The double-sided display pixel package structure according to claim 1, wherein the half mirror film has a thickness of 20˜70 nm.

12. A method for fabricating a double-sided display pixel package structure comprising:
providing a transparent substrate penetrated with conduction via sets, wherein each of the conduction via sets includes conduction vias;
respectively forming conduction bumps on the conduction vias of each of the conduction via sets;
respectively forming a dummy diode structure and light-emitting diode structures on the conduction bumps;
forming a first protection layer on the transparent substrate to surround and cover the conduction bumps, the dummy diode structure, and the light-emitting diode structures;
removing the first protection layer on tops of the dummy diode structure and the light-emitting diode structures;
forming a conduction layer on the first protection layer, the dummy diode structure, and the light-emitting diode structures to electrically connect to the dummy diode structure and the light-emitting diode structures;
forming a second protection layer on the conduction layer;
dividing the transparent substrate, the first protection layer, the conduction layer, and the second protection layer to form diode package structures, wherein each of the diode package structures includes the conduction via set and the transparent substrate, the conduction bumps, the dummy diode structure, the light-emitting diode structures, the first protection layer, the conduction layer, and the second protection layer corresponding thereto;
arranging the diode package structures on a transient substrate through a removable double-sided adhesive layer;
forming a half mirror film on sidewalls of the transparent substrate, the first protection layer, the conduction layer, and the second protection layer and a partial top of the second protection layer of each of the diode package structures, so as to expose the second protection layer which is directly formed over the light-emitting diode structures; and
removing the removable double-sided adhesive layer and the transient substrate from the diode package structures and the half mirror film to obtain double-sided display pixel package structures.

13. The method for fabricating a double-sided display pixel package structure according to claim 12, wherein the step of forming the half mirror film on the sidewalls of the transparent substrate, the first protection layer, the conduction layer, and the second protection layer and the partial top of the second protection layer of each of the diode package structures, so as to expose the second protection layer which is directly formed over the light-emitting diode structures comprises:
respectively arranging blocking blocks on the second protection layer which is directly formed over the light-emitting diode structures;
forming the half mirror film on the blocking blocks and the sidewalls of the transparent substrate, the first protection layer, the conduction layer, and the second protection layer and the partial top of the second protection layer of each of the diode package structures; and
removing blocking blocks and the half mirror film thereon.

14. The method for fabricating a double-sided display pixel package structure according to claim 12, wherein the transparent substrate of each of the diode package structures has a shape of a square, the diode package structures on the transient substrate are uniformly spaced, and a distance between adjacent two of the diode package structures is 1.2 times a width of the square.

15. The method for fabricating a double-sided display pixel package structure according to claim 12, wherein the removable double-sided adhesive layer is an ultraviolet rays (UV) release adhesive layer.

16. The method for fabricating a double-sided display pixel package structure according to claim 12, wherein each of the light-emitting diode structures includes:
a metal combined substrate including a first Invar layer, a first copper layer, and a second copper layer, the first copper layer and the second copper layer are respectively formed on a top surface and a bottom surface of the first Invar layer, the second copper layer is formed between the first Invar layer and the conduction bump, and a thickness ratio of the first copper layer to the first Invar layer to the second copper layer is 1:2.5˜3.5:1;
a first epitaxial layer, having a first conductivity type, formed on the first copper layer;
a second epitaxial layer, having a second conductivity type opposite to the first conductivity type, formed on the first epitaxial layer; and
an electrode layer formed on the second epitaxial layer, the first protection layer surrounds the metal combined substrate, the first epitaxial layer, the second epitaxial layer, and the electrode layer, and the conduction layer is formed on the electrode layer.

17. The method for fabricating a double-sided display pixel package structure according to claim 16, wherein the dummy diode structure includes a second Invar layer, a first gold layer, and a second gold layer, the first gold layer and the second gold layer are respectively formed on a top surface and a bottom surface of the second Invar layer, the second gold layer is formed between the second Invar layer and the conduction bump, and a thickness ratio of the first gold layer to the second Invar layer to the second gold layer is 1.1:2.5˜3.5:1.1.

18. The method for fabricating a double-sided display pixel package structure according to claim 12, wherein in the step of forming the first protection layer to cover the light-emitting diode structures, a height of the first protection layer minus a height of each of the light-emitting diode structures is equal to 4˜8 μm.

19. The method for fabricating a double-sided display pixel package structure according to claim 12, wherein in the step of respectively forming the dummy diode structure and the light-emitting diode structures on the conduction bumps, a laser with a power of 1˜5 watts is applied to the conduction bumps for 15˜60 ms to form the dummy diode structure and the light-emitting diode structures on the conduction bumps respectively.

20. The method for fabricating a double-sided display pixel package structure according to claim 12, wherein the light-emitting diode structures include green light-emitting diode structures, blue light-emitting diode structures, and red light-emitting diode structures.
